(19) United States
(12) Patent Application Publication
(10) Pub. No.: US 2007/0251449 A1
(43) Pub. Date: Nov. 1, 2007

(54) Coating Film Forming Apparatus and Coating Film Forming Method

(75) Inventors: Tsuyoshi Mizuno, Kumamoto-ken (JP); Kimihide Saito, Osaka-Fu (JP); Yuuichi Mikata, Kanagawa-Ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignees: Tokyo Election Limited, Tokyo (JP); Sanyo Electric Co., Ltd, Osaka-fu (JP); Kabushiki Kaisha Toshiba, Tokyo (JP)

(21) Appl. No.: 10/574,547

(22) PCT Filed: Oct. 1, 2004
(86) PCT No.: PCT/JP04/14503

§ 371 Date: Mar. 26, 2007

(30) Foreign Application Priority Data
Oct. 2, 2003 (JP) 2003-344753

(51) Int. Cl. H01L 21/31; H01L 21/30; H01L 21/312

(52) U.S. Cl. 118/668; 427/58

(57) ABSTRACT

The object of the present invention is to assuredly merge adjacent coating liquid lines when a coating liquid is applied on a surface of a substrate by a so-called scan coating. The coating is performed while the wafer W is oriented to an orientation such that the scanning direction of the coating nozzle liquid 5 crosses at the dicing lines D formed on the wafer W. After completion of the application, the wafer W is returned to the original orientation and thereafter the wafer W is unloaded from a coating film forming apparatus. The coating film forming apparatus stores a plurality of recipes defining coating conditions for each kind of wafer W. The coating conditions defined by the recipes include the orientation of the wafer W. The orientation of the wafer W is automatically set based on the selected recipe.

### TECHNICAL FIELD

The present invention relates to a coating film forming apparatus and a coating film forming method, for forming a coating film on a substrate in a semiconductor device manufacturing process.

### BACKGROUND ART

A CVD film deposition method has been in prevalent use for manufacturing an insulating film such as an interlayer insulating film of a semiconductor device. There has been recently proposed a method of applying a coating liquid, which is prepared by dissolving a precursor of a silicon oxide film in a solvent, on a surface of a substrate such as a semiconductor wafer to form thereon a liquid film, and vaporizing the solvent from the liquid film, so as to for an insulating film of a silicon oxide film.

A typical method of applying a coating liquid to a surface of a substrate is a spin-coating method that supplies a coating liquid onto a center of a substrate, and rotates the substrate to spread the coating liquid by a centrifugal force. However, when the coating liquid is applied to a large-sized substrate by the spin-coating method, a film thickness is undesirably prone to be non-uniform due to turbulence of air occurring at an outer peripheral portion of the substrate. In addition, a considerably large amount of coating liquid is scattered and thus is wasted in the spin-coating method. In order to solve these problems, an apparatus for applying a coating liquid to a substrate has been recently proposed in which, instead of rotating a substrate, a nozzle that continuously dispenses a coating liquid is moved in a meandering manner relative to the substrate (see, JP2001-237179A, specifically paragraphs 0035 to 0045, and FIGS. 7 and 15).

FIG. 15 schematically shows the operation of the apparatus disclosed in JP2001-237179A. A liquid coating nozzle 110 opposed to a surface of a wafer W reciprocates in X-direction while dispensing a coating liquid 111. At the same time, the wafer W is intermittently fed in Y-direction, so that a meandering coating liquid line is formed on the water W. A pair of liquid receivers (not shown), which move in X-direction depending on the Y-position of the wafer W to constantly locate at positions near the edge of the wafer W, receive the coating liquid dispensed from the nozzle 110 near turning positions of the nozzle 110. Thus, adhesion of the coating liquid to a periphery of the wafer W and a rear surface thereof can be prevented.

A V-shaped notch N indicating the orientation of the wafer W is formed in the periphery of the wafer W. As shown in FIG. 16, dicing lines for dividing the wafer W into discrete chips extend on the surface of the wafer W in directions parallel to and perpendicular to a line connecting the notch N and the wafer center.

The coating liquid is applied such that the line connecting the notch N and the wafer center is parallel to the feeding direction of the wafer W (Y-direction). Wiring patterns are formed on the wafer surface and the wiring patterns generally extend in a direction parallel to or perpendicular to the dicing lines. Thus, the moving direction of the nozzle and the direction of the wiring patterns are parallel to each other.

In this situation, as shown in FIG. 17, the wiring patterns P having a large space width, or wiring patterns P having a large height or large depth prevent adjacent coating liquid lines L from contacting each other, and thus there remains an area on the wafer surface which is not coated with the coating liquid. Such a phenomenon may also occur rear the dicing lines, when the dicing lines are wide or deep.

### SUMMARY OF THE INVENTION

An object of the present invention is to provide a coating film forming apparatus and a coating film forming method, that are capable of assuredly applying a coating liquid on the whole surface of a substrate to form thereon a coating film, when the coating liquid is applied on the surface of the substrate by scanning the substrate by a liquid coating nozzle relatively.

The present invention is a method of forming a coating film on a surface of a substrate on which patterns of grooves or ridges are formed, by dispensing a coating liquid from a liquid coating nozzle, characterized in that the liquid coating nozzle and a substrate holding member are moved relative to each other such that the liquid coating nozzle linearly scans the substrate to cross a certain pattern on the substrate held horizontally. The term “horizontally” herein includes a substantially horizontal state.

To be specific, the present invention includes a step of horizontally holding the substrate by a substrate holding member; a step of orienting the substrate in an orientation such that a specific pattern of the patterns formed on the surface of the substrate crosses a scanning direction of the liquid coating nozzle; and a step of making the liquid coating nozzle linearly scan the substrate relatively, while dispensing a coating liquid from the liquid coating nozzle.

The present invention can be embodied as a method of applying a coating liquid or a substrate, by drawing a continuous coating liquid line without any discontinuity on the substrate. Substrates to which the present invention can be applied include a substrate for manufacturing a semiconductor integrated circuit element such as a wafer, a glass substrate for a liquid crystal display, and the like. In this case, the present invention includes a step of arranging a plurality of linear coating liquid lines in a forward-and-backward direction, by repeating an operation in which the liquid coating nozzle is moved in a right-and-left direction to linearly apply the coating liquid on the surface of the substrate, and an operation in which the substrate holding member is moved relative to the liquid coating nozzle in the forward-and-backward direction at a preset pitch.

The present invention is applicable to a method of forming a coating film by using a liquid coating nozzle provided with a plurality of linearly-arranged dispense ports for dispensing the coating liquid, and by making the liquid coating nozzle linearly scan the substrate relatively, from one end of the substrate to the other end thereof.

The step of orienting the substrate is performed by rotating the substrate holding member. In the event that the substrate is a semiconductor wafer, dicing lines, for dividing the substrate into a plurality of chips each serving as a semiconductor integrated circuit element, are longitudinally and transversely formed on the substrate, and the step of orienting the substrate may comprise a step of orienting the substrate such that the scanning direction of the liquid coating nozzle crosses all the dicing lines. The present invention may further include a step of returning the substrate to an orientation in which the substrate was oriented when the substrate was delivered to the substrate holding member before starting of a coating process, prior to removing the substrate having been subjected to the coating process from the substrate holding member. The step of orienting the substrate may comprise a step of retrieving, from data stored in storing means which data is structured so as to associate kinds of substrates with orientations of the substrates, an orientation of the substrate corresponding to a kind of the substrate to be coated, and a step of orienting the substrate in the retrieved orientation.

In one embodiment, the present invention further comprises a step of imaging the surface of the substrate, wherein the step of orienting the substrate comprises a step of determining a direction of the pattern based on an imaging result, and a step of orienting the substrate depending on the determined direction of the pattern. In this case, the step of orienting of the substrate comprises a step of making the substrate be in the orientation based on a determination result determined based on the imaging result, and data structured so as to associate directions of patterns with orientations of the substrates.

In addition, the present invention provides an apparatus for forming a coating film on a surface of a substrate on which patterns of grooves or ridges are formed. The apparatus is characterized by including: a substrate holding member adapted to support a substrate horizontally; a liquid coating nozzle opposed to the substrate held by the substrate holding member, the liquid coating nozzle being adapted to dispense a coating liquid to the substrate; angle setting means for orienting the substrate in an orientation such that a specific pattern of the patterns formed on a surface of the substrate crosses a scanning direction of the liquid coating nozzle; and a driving mechanism adapted to cause the liquid coating nozzle to be moved relative to the substrate holding member such that the liquid coating nozzle linearly scans the substrate relatively.

The apparatus according to the present invention can be embodied as an apparatus for applying a coating liquid on a substrate, by drawing a continuous coating liquid line without any discontinuity on the substrate. In this case, the apparatus further comprises a first driving mechanism adapted for movement of the substrate holding member in a forward-and-backward direction relative to the liquid coating nozzle, and a second driving mechanism adapted to move the liquid coating nozzle in a right-and-left direction, whereby a plurality of linear coating liquid lines are arrayed in the forward-and-backward direction to form a film of the coating liquid on the substrate, by repeating an operation in which, after the liquid coating nozzle is moved in the right-and-left direction while liquid coating nozzle dispenses the coating liquid, the substrate holding member is moved in the forward-and-backward direction relative to the liquid coating nozzle at a preset pitch.

When using a liquid coating nozzle with a plurality of linearly-arranged dispense ports for dispensing the coating liquid, the driving mechanism is configured to move the liquid coating nozzle relative to the substrate holding member so that the liquid coating nozzle to linearly scan the substrate relatively from one end of the substrate to the other end thereof.

Examples of concrete embodiments of the apparatus according to the present invention are as follows. The substrate holding member is capable of rotating, and the angle setting means configured to rotate the substrate holding member to orient the substrate in the orientation. Dicing lines, for dividing the substrate into a plurality of chips each serving as a semiconductor integrated circuit element, are longitudinally and transversely formed or the substrate and the angle setting means is configured to orient the substrate such that a scanning direction of the liquid coating nozzle crosses all the dicing lines. There is provided means for returning the substrate to an orientation in which the substrate was oriented when the substrate was delivered to the substrate holding member before starting of a coating process, prior to removing the substrate having been subjected to the coating process from the substrate holding member. The angle setting means includes means for storing data structured so as to associate kinds of substrates with orientations of the substrates, and means for retrieving, from data stored in the storing means, an orientation of the substrate corresponding to a kind of the substrate to be coated, and for orienting the substrate in the retrieved orientation.

The apparatus according to the present invention may further comprise image-pickup means for imaging the surface of the substrate. In thus case, the angle setting means may be configured to determine a direction of a pattern based on an imaging result obtained by the imaging means, and configured to orient the substrate to an orientation depending on the determined direction of the pattern. Also in this case, the angle setting means may include storing means for string data structured so as to associate directions of patterns with orientations of the substrates, and means for orienting the substrate in an orientation based on a determination result determined based on the imaging result and on the data stored in the storing means.

According to the present invention, the scanning direction of the liquid coating nozzle crosses a specific pattern of the patterns formed on the substrate, which might obstruct contact of adjacent coating liquid lines if the coating liquid would be applied under conditions that the specific pattern is in parallel with the coating liquid lines. Thus, the adjacent coating liquid lines assuredly come into contact with each other and merge with each other over the pattern, without being obstructed by the pattern. Note that, in the event that scan coating is performed by using the liquid coating nozzle provided with a plurality of dispense ports, “coating liquid lines” herein mean lines of coating liquid dispensed from the respective dispense ports. Therefore, defects such as thin spots of the coating liquid can be prevented in the area in which the specific pattern is formed. Consequently, the coating liquid can be applied uniformly to all over the area to be coated of the substrate. In the case of a wafer on which the dicing lines are longitudinally and transversely formed, since the dicing lines and the scanning direction of the liquid coating nozzle cross each other, the adjacent coating liquid lines assuredly come into contact with each other over the pattern parallel to the dicing lines. In addition, since the dicing lines do not obstruct the contacting of adjacent coating liquid lines, there is no possibility that a uneven coating film is formed near the dicing lines.

### BRIEF DESCRIPTION OF THE DRAWINGS

FIG. 1 is a longitudinal cross-sectional view of showing the structure of a coating film forming apparatus according to the present invention;

FIG. 2 is a partial cross-sectional view of the coating film forming apparatus shown in FIG. 1 viewed from the above;

FIG. 3 is a perspective view of showing the structure of a nozzle unit shown in FIG. 1;

FIG. 4 is an explanatory drawing illustrating a control system of the coating film forming apparatus shown in FIG. 1;

FIG. 5 is a plan view showing the angular relationship among a coating liquid line, a notch and dicing lines, for illustrating a coating film forming method performed by the coating film forming apparatus shown in FIG. 1;

FIG. 6 is an explanatory drawing illustrating the relationship between the adjacent coating liquid lines and a wiring pattern;

FIG. 7A is an explanatory drawing illustrating the experiment result for comparing a conventional application method with a application method according to the present invention;

FIG. 7B is an explanatory drawing illustrating the experiment result for comparing a conventional application method with the coating method according to the present invention;

FIG. 8 is an explanatory drawing illustrating a control system of the coating film forming apparatus in another embodiment of the present invention;

FIG. 9 is shows a detailed structure of an angle setting table shown in FIG. 8;

FIG. 10 is a perspective view schematically showing a liquid coating nozzle and peripheral parts in the coating film forming apparatus in still another embodiment of the present invention;

FIG. 11 is a side view showing the operation of the liquid coating nozzle shown in FIG. 10;

FIG. 12 is a schematic plan view showing a moving mechanism of the liquid coating nozzle shown in FIG. 10 and the coating operation thereof;

FIG. 13 is a perspective view schematically showing an coating system which the coating film forming apparatus according to the present invention is incorporated;

FIG. 14 is a plan view schematically showing the internal structure of the coating system shown in FIG. 13;

FIG. 15 is an explanatory drawing illustrating a conventional coating film forming method;

FIG. 16 is an explanatory drawing illustrating a conventional coating film forming method; and

FIG. 17 is an explanatory drawing illustrating the conventional coating film forming method.

### BEST MODE FOR CARRYING OUT THE INVENTION

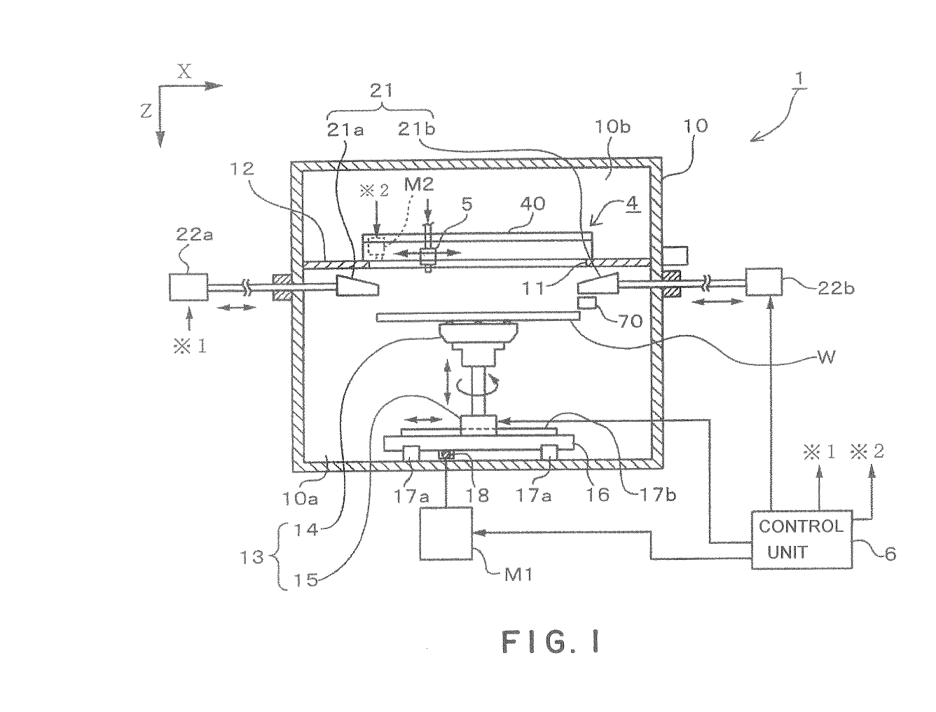

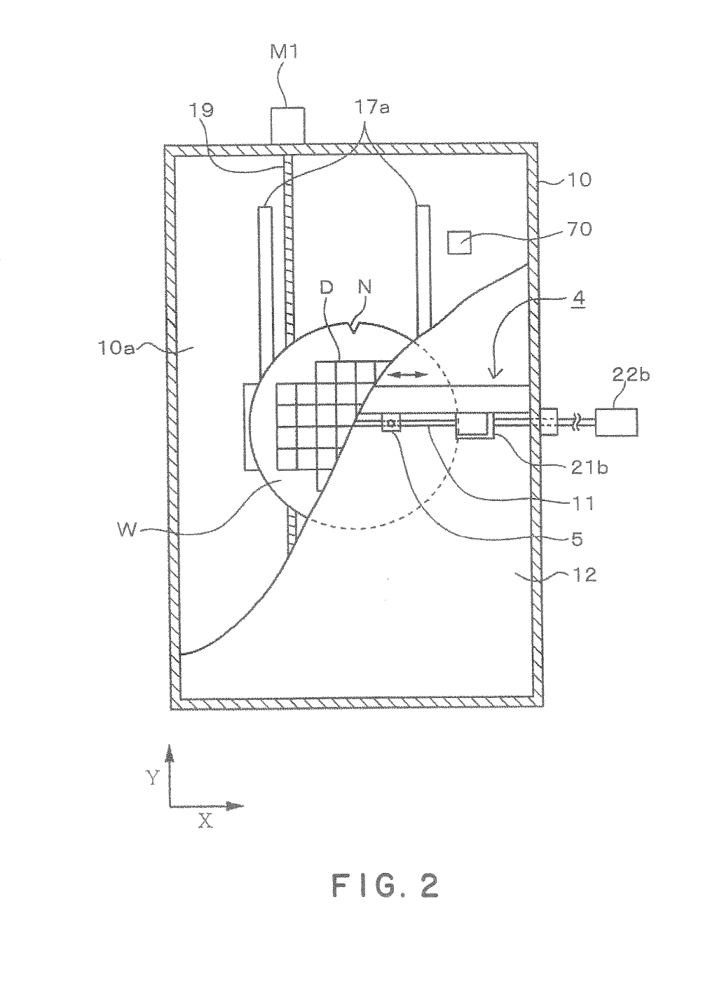

Embodiments of the coating film forming apparatus and the coating film forming method according to the present invention will be described in detail with reference to the accompanying drawings. First, the structure of the coating film forming apparatus 1 is described with reference to FIGS. 1 and 2. The reference number 10 depicts a housing. An internal space of the housing 10 is divided into upper and lower portions thereof by a partition plate 12 with a slit 11 formed in a center thereof. Clean-air downflow is generated by airflow generating means, not shown, in the internal space of the housing 10. The length of the slit 11 (dimensions in the right-and-left direction in FIG. 1) is slightly larger than the maximum width of an area to be coated in a surface of a wafer W.

A part of the periphery of the wafer W is cut out to form a notch N indicating the orientation of the wafer W. Dicing lines D like a grid, which are used for dividing the wafer W into discrete semiconductor element chips have been previously formed on the surface of the wafer W in directions parallel to and perpendicular to a line passing through the notch N and the center of the wafer W. Wiring patterns of ridges are formed on the surface of the wafer W along the dicing lines D.

First, component members arranged in a lower space 10a below the partition plate described. The reference number 13 represents a substrate holding unit that includes: a sucking device (substrate holding member) 14 for sucking the rear surface of the wafer W to hold the same in substantially a horizontal posture; and a driving base 15 capable of moving in X-direction, having a driving mechanism for vertically moving the sucking device 14 and rotating the same about a vertical axis. The driving base 15 is supported by a moving member 16 at its lower end.

Two rails 17a extending in Y-direction are disposed on a bottom surface of the housing 10. A guide rail 17b is disposed on an upper surface of the moving member 16 to guide the driving base 15 in X-direction. By moving the driving base 15 and the moving member 16, the wafer W held by the substrate holding unit 13 is capable of moving to any position in X-, and Y-directions in the lower space 10a. A ball screw 18 having a screw shaft extending in a direction parallel to the rails 17a is disposed at a position near a lower surface of the moving member 16. When the screw shaft is rotated by a rotor M1, the moving member 16 is moved in Y-direction, while being guided by the rails 17a. The moving member 16 the rails 17a, the ball screw 18, and the motor M1 constitute a holding-member driving mechanism (second driving mechanism) that moves the substrate holding unit 13 and the wafer W held by the same relative to a liquid coating nozzle 5 in a forward-and-backward direction (Y-axis direction in FIG. 2).

In the lower space 10a, a notch position detector 70, which detects the position of the notch N of the wafer W to identify the orientation of the wafer W, is arranged at a level substantially the same as that of the wafer W. The notch position detector 70 schematically shown in FIG. 1 has generally a square bracket shape. When the notch position detector 70 is in its detecting position, the periphery of the wafer W is located between an upper beam and a lower beam of the notch position detector 70. The notch position detector 70 is provided with a photo-sensor having a light-emitting element and a light-receiving element which are respectively arranged on the upper and the lower beams. The position of the notch N can be detected by driving the ball screw 18 to move the wafer W to an upper position. In FIG. 2 so that the periphery of the wafer W intercepts the optical axis of the photo-sensor, and by rotating the wafer W about the vertical axis by 360 degrees. In this embodiment, the orientation (angular position) of the wafer W when a coating liquid is applied thereon is set based on the detected position of the notch N.

A pair of liquid receivers 21 (21a, 21b), which receive the coating liquid dropping from the nozzle 5 to prevent the coating liquid from being supplied to the outer peripheral area of the wafer W, are arranged in positions below the partition plate 12 corresponding to the slit 11. Each of the liquid receivers 21 (21a, 21b) has a tray-like shape for receiving and collecting the dropping coating liquid. Each of the liquid receivers 21 are provided with a cleaning mechanism (not shown) for flushing the coating liquid adhering the surface of the liquid receivers 21, and a drain line (not shown) for discharging the received coating liquid outside the housing 10. Forward-and-backward driving mechanisms 22 (22a, 22b) bring the liquid receivers 21a and 21b in X-direction away from or close to each other, in such a manner that distal ends of the pair of respective liquid receivers 21 are positioned slightly inside the outer periphery of the wafer W, irrespective of Y-position of the wafer W. In other words, the forward-and-backward driving mechanism 22 changes a gap between the liquid receivers 21a and 21b with respect to X-direction in order that the distal ends of the pair of liquid receivers 21a and 21b are positioned slightly inside the outer periphery of the wafer W, irrespective of Y-position of the wafer W, while constantly keeping a symmetrical positional relationship between the liquid receivers 21a and 21b with respect to the line passing through the center of the wafer W in Y-direction.

The liquid coating nozzle 5 for applying the coating liquid on the surface of the wafer W is arranged above an area where the liquid receivers 21 (21a, 21b) are moved. The liquid coating nozzle 5 is disposed in a nozzle unit 4.

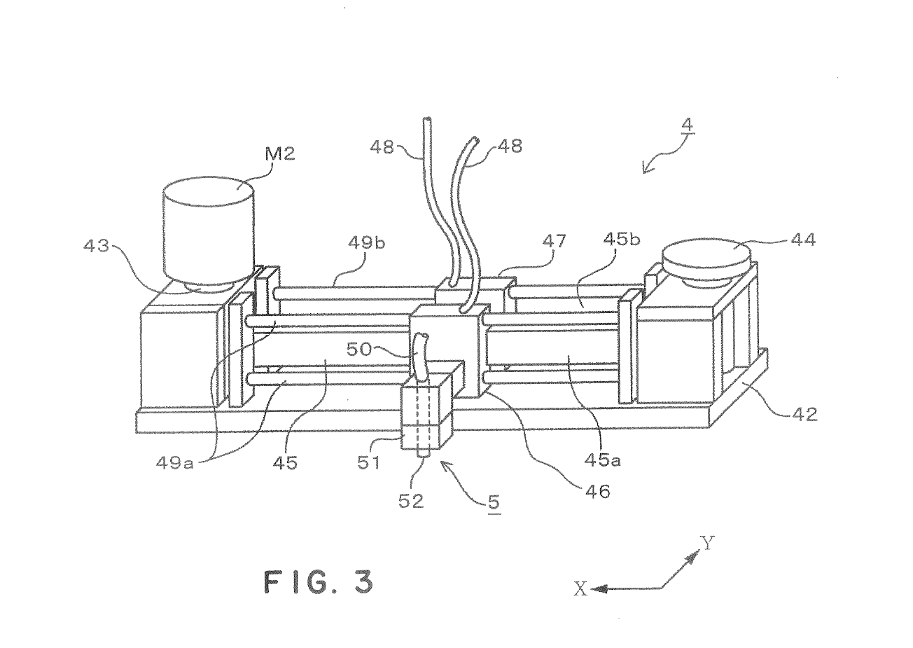

As shown in FIG. 3, the unit 4 includes: a base member 42 of a rectangular plate shape extending in X-direction; a drive pulley 43 and a driven pulley 44 respectively disposed on opposite ends of the base member 42; and an endless belt 45 wound around the pulleys 43 and 44. When a motor M2 drives the drive pulley 43 for rotation, the endless belt 45 is driven in a direction corresponding to the rotational direction of the motor M2. The liquid coating nozzle 5 is attached to one belt portion 45a through a nozzle supporting member 46. A balancer weight 47 for preventing oscillations is attached to the other belt portion 45b. The balancer weight 47 has a weight equivalent to the weights of the liquid coating nozzle 5 and the nozzle supporting member 46, and moves in a direction opposite to the liquid coating nozzle 5 and the nozzle supporting member 46. The reference numbers 49a and 49b depict guide shafts. The guide shafts 49a and 49b respectively incorporate air guiding mechanisms (not shown) into which air is supplied from air supply pipes 82. The nozzle supporting member 46 and the balancer 47 are guided by the guide shafts 49a and 49b via the air guiding mechanisms. The drive pulley 43, the driven pulley 44, the endless belt 45, the nozzle supporting member 46, and the balancer 47 constitute a nozzle driving mechanism (first driving mechanism) which drives the liquid coating nozzle 5.

In FIG. 3, the reference number 50 depicts a coating-liquid supply pipe; 51 depicts a nozzle body; and 52 depicts a dispense port. The dispense port 52 has a bore of, e.g., 50 μm.

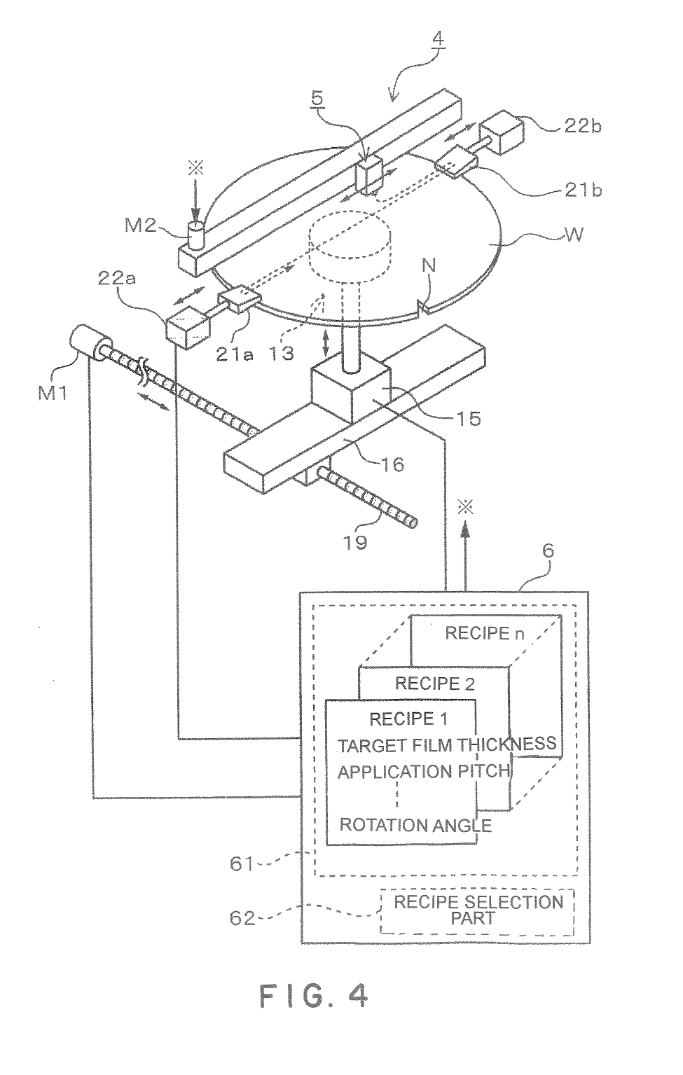

Referring to FIG. 4, a control system of the coating film forming apparatus is described. A control unit 6 has such a function that controls through respective not-shown controllers, the motor M1 for driving the substrate holding unit 13, the forward-and-backward driving mechanisms 22 (22a, 22b), and the motor M2 for moving the liquid coating nozzle 5.

A storing part 61 of the control unit 6 stores a plurality of recipes. Each recipe includes a plurality of recipe data that define coating conditions such as a target film thickness of the coating film, an application pitch and an orientation of the wafer W when a coating liquid is applied thereon. A recipe selection part 62 of the control unit 6 selects one of the recipes stored in the storing part 61, depending on a kind of the wafer W or a composition of the coating liquid. The control unit 6 controls the respective mechanisms in the coating film forming apparatus through a control program based on the selected recipe, so as to perform a coating process.

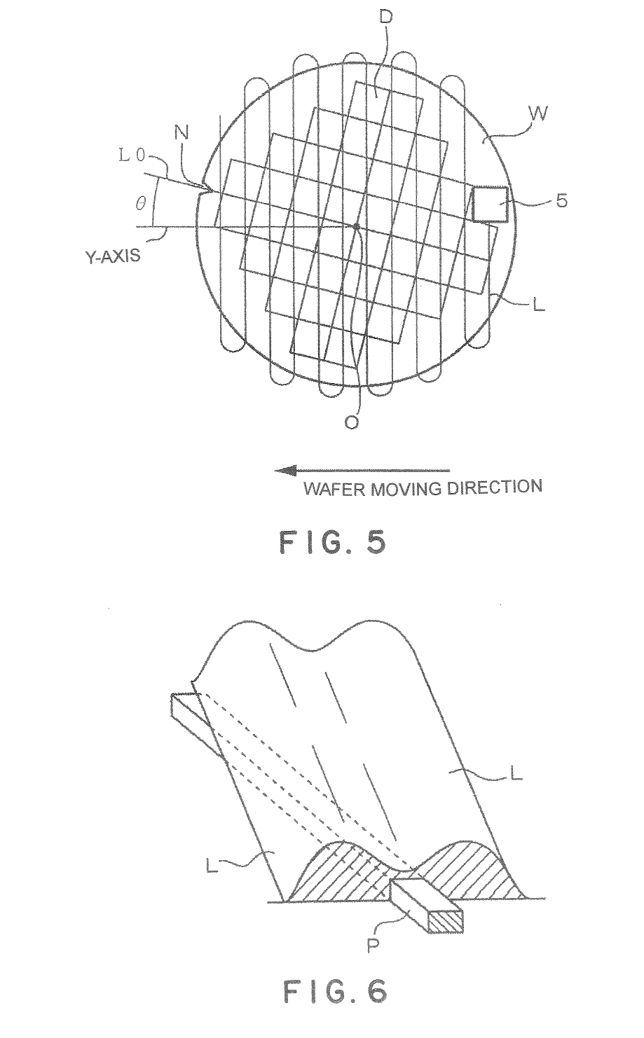

The “orientation of the wafer” as one of the recipe data means a direction in which the notch N showing the direction of the crystal of the wafer W is oriented, when the coating liquid is applied onto the wafer W by the liquid coating nozzle 5. Specifically as shown in FIG. 5 the “orientation of the wafer” is defined by an angle θ formed by a line L0 connecting the notch N and the center of the wafer W with respect to the moving direction (Y-direction) of the wafer W. In this embodiment, the orientation of the notch 3 is set such that a scanning direction of the liquid coating nozzle 5 and the wiring patterns of the wafer W are not parallel to each other. As stated above, the wiring patterns on the wafer W generally extend in a direction parallel to or perpendicular to the dicing lines D. Thus, at first, the orientation of the wafer W is decided such that the scanning direction of the liquid coating nozzle 5 is not parallel to any of the dicing lines D. However, some kind of the wafer has a wiring pattern group including wiring patterns that do not extend parallel to the dicing lines D, but extend at an angle of 30°, 45°, or 60° relative to the dicing lines D. Directions of such wiring patterns should not be parallel to the scanning direction of the liquid coating nozzle 5 in some cases, depending on dimensions of the wiring patterns, such as width and height thereof. In this case, the orientation of the wafer W (angle θ) is decided, considering the angular relationship of the scanning direction of the liquid coating nozzle 5 relative not only to the dicing lines D but also to the wiring patterns.

Based on the recipe data retrieved from the storing part 61, the control unit 6 sets a rotation angle of the wafer W held by the substrate holding unit 13, by a not-shown motor incorporated in the driving base 15. In the illustrated embodiment, the storing part 61 storing the recipes, the program that retrieves a rotation angle defined in the recipe and gives a control signal to the driving base 15, and the like correspond to “angle setting means”.

Next, operations of the coating film forming apparatus are described with reference to FIGS. 5 to 7.

First, an operator selects a predetermined recipe corresponding to the kind of the wafer W (for example, corresponding to the production lot of the wafer W) by means of the recipe selection part 62. The coating film forming apparatus is brought into operation, and the wafer W is loaded into the housing 10 from outside. The substrate holding unit 13 sucks the rear surface of the wafer W to horizontally hold the same. The wafer W is loaded into the housing 10 via an inlet port, not shown, disposed on the lower side of FIG. 2. Then, the wafer W is moved by the substrate holding unit 13 to a position where the notch position detector 70 is located, and the position of the notch N of the wafer W is detected by the notch position detector 70. Based on the detected position of the notch N, the orientation of the wafer W is adjusted by rotating the substrate holding unit 13 at an angle corresponding to a rotation angle of the wafer W defined in the recipe. It is often the case that the orientation of the wafer W has been previously adjusted before it is loaded into the coating film forming apparatus. However, ever in this case, the orientation of the wafer W is confirmed by the notch position detector 70 in order to make it sure that the wafer W is accurately positioned. Next, the substrate holding unit 13 is moved to its coating-start position where a front end of the wafer W held by the substrate holding unit 13 is located below the range of movement of the liquid coating nozzle 5. Meanwhile, the liquid receivers 21 (21a, 21b) are respectively located in predetermined positions which are slightly inside outer peripheral edge of the wafer W. Thereafter, the liquid coating nozzle 5 dispensing the coating liquid is reciprocated in X-direction at a predetermined speed of, e.g., 2 m/sec., while the wafer W is intermittently fed by the moving member 16 in Y-direction at the right times when the liquid coating nozzle 5 just reverses moving direction. In this manner, a meandering, continuous (without any discontinuity) coating liquid line can be drawn on the wafer W. Actually, every time when the liquid coating nozzle C reverses its moving direction, the coating liquid dispensed therefrom is interrupted by the liquid receiver 21, so that there are formed on the wafer W a plurality of coating liquid lines extending in X-direction and spaced at Y-direction intervals. The coating liquid in this embodiment is, for example, a solvent in which a precursor of an insulation film is dissolved.

FIG. 5 shows the state in which the coating liquid is applied on the surface of the wafer W. The reference character L indicates the coating liquid lines applied by the liquid coating nozzle 5. A line width of each line L is, e.g., 1.2 mm, and a pitch thereof (a distance between centers of adjacent coating liquid lines L with respect to Y-direction) is, e.g., 0.5 mm to 1.0 mm. After the coating liquid is applied on the wafer W, the coating liquid spreads such that the width of the coating liquid lines L with respect to Y-direction becomes wider. If the coating liquid lines L and the wiring pattern are parallel to each other, there is a possibility that spreading of the coating liquid might be obstructed by the wiring pattern. However, in this embodiment, as shown in FIG. 6, since the coating liquid lines L cross the wiring pattern P, a coating liquid line L and an adjacent coating liquid line L spread over a wiring pattern P. That is, the adjacent coating liquid lines L come unfailingly into contact with each other over the wiring pattern P, so that the coating liquid begins to further spread from the contacting point. As a result, the adjacent coating liquid lines can assuredly merge with each other. Although the above explanation is made about the wiring pattern P of a ridge shape, it is also true with a wiring pattern of a groove shape formed in a circuit part. When there is a groove pattern which may possibly obstruct the merging of the adjacent coating liquid lines, the orientation of the wafer W is such that the direction of the groove pattern crosses the coating liquid lines L. Due to this orientation of the wafer W, the adjacent coating lines L can properly merge with each other, with the same mechanism as stated above.

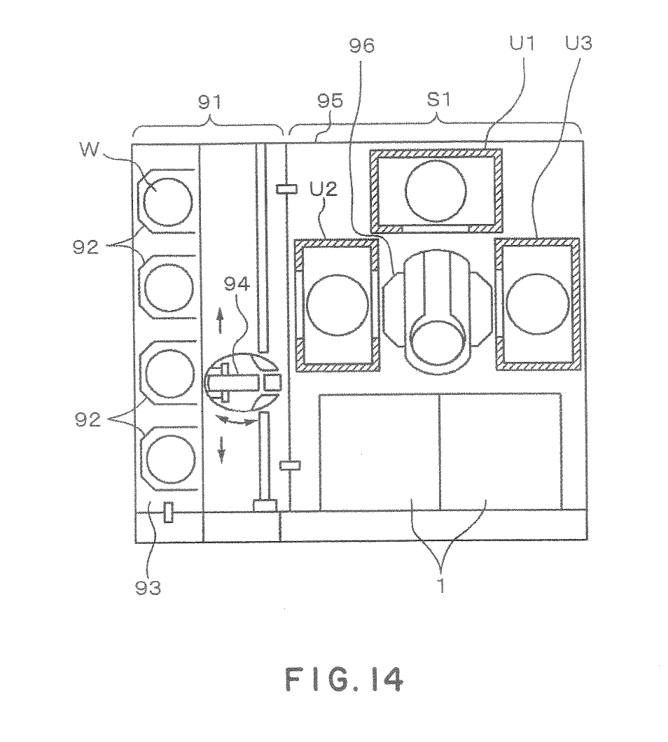

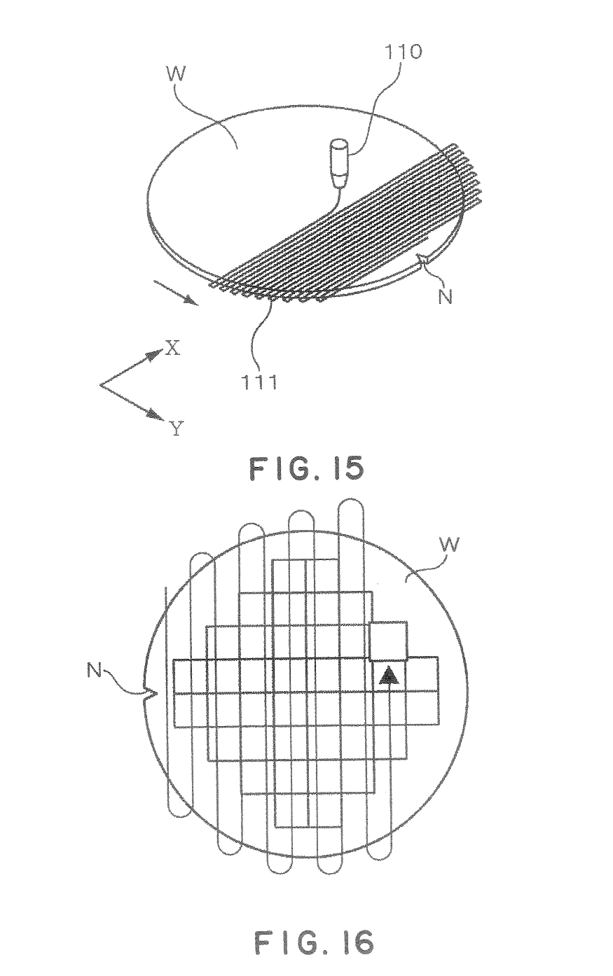

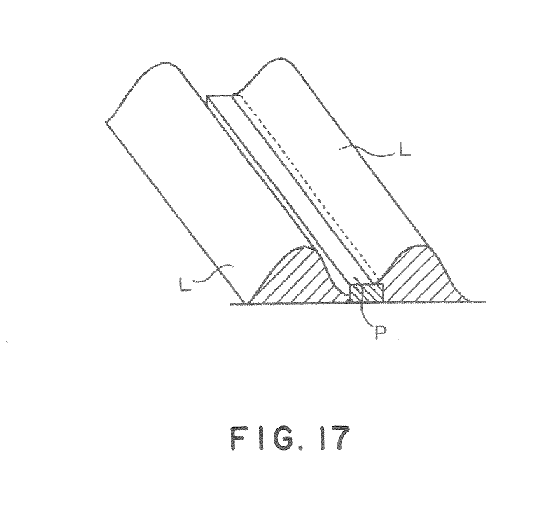

After the scan coating by the liquid coating nozzle 5 to a rear end of the wafer W is completed, that is, the coating liquid is applied all over the effective area (area where devices are formed) of the wafer W, the driving base 15 is operated through a program in the control unit 6 to adjust the orientation of the wafer W to a predetermined orientation. After coating film such as an insulation film is formed on the wafer W, the wafer W is subjected to treatments such as a heating process and the like. Throughout these treatments, the wafer W is constantly oriented in the same direction to allow analysis of process conditions of the wafer W. When the wafer W is conveyed, for example, by a main arm 96 arranged in a system shown in FIG. 14, which will be described later, the orientation of the wafer W is generally adjusted such that the notch N is positioned on a front side or a rear side. To this end, after completion of the application (coating) operation, the orientation of the wafer W is adjusted by the driving base 15 such that the wafer W is conveyed with the wafer W being directed to such an orientation (predetermined orientation). In general, the wafer W is loaded into the coating film forming apparatus with the notch N being positioned on the front side or the rear side. That is, when unloaded, the orientation of the wafer W is returned to the same orientation when it was loaded into the coating film forming apparatus.

In the above embodiment, since the scanning direction of the liquid coating nozzle 5 crosses the dicing lines D, a certain wiring pattern (a wiring pattern in which part(s) thereof not coated with the coating liquid may possibly exist if the wiring pattern is parallel to the coating liquid lines L) parallel to the dicing lines D crosses the coating liquid lines L, which makes it sure that adjacent coating liquid lines come into contact with each other. Since the coating liquid can be applied all over the effective area of the surface of the wafer W, a process yield can be improved. When the scanning direction of the liquid coating nozzle 5 and the dicing lines D are parallel to each other, there may be a case in which adjacent coating liquid lines L are not merged with each other. However, in this embodiment, since the dicing lines D and the coating liquid lines L cross each other, the coating film can be formed on the dicing lines D without fail.

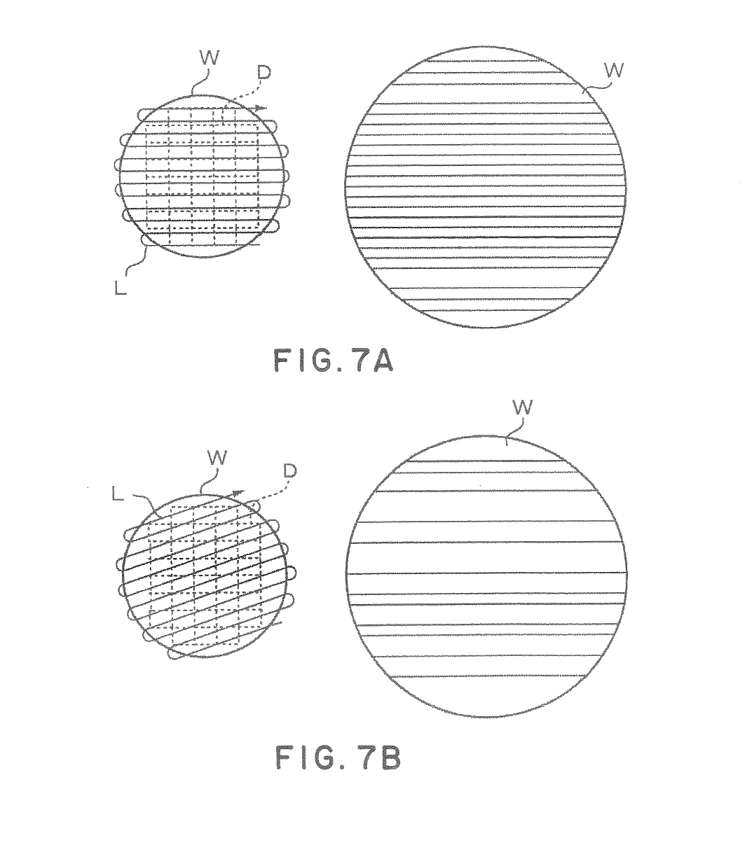

Experiments were conducted to confirm effects of the present invention. The experiment results are described below with reference to FIGS. 7A and 7B. The coating liquid was applied in such a manner that the coating liquid lines L and the dicing lines D extending in the right-and-left direction in FIG. 7A were parallel to each other FIG. 7A). On the other hand, the coating liquid was applied in such a manner that the coating liquid lines L and the dicing lines D crossed each other (FIG. 7B). The surface of the wafer W used in the experiments was formed of an oxide film layer on which groove patterns of a plurality of grooves, each having a width of 10 μm to 20 μm, at an interval of 10 μm to 100 μm, were formed in parallel with the dicing lines D. The coating liquid lines L had a line width of 1.2 mm, and a pitch of 0.5 mm. The film thickness of the insulation film was 800 μm.

The left illustrations of FIGS. 7A and 7B show the manner in which the coating liquid was applied on the surface of the wafer W. The right illustrations of FIGS. 7A and 7B show the wafer W on which the coating liquid was applied. Lines extending in the right-and-left direction represent areas not coated with the coating liquid.

In the event that the coating liquid was applied such that the dicing lines D and the coating liquid lines L were parallel to each other as shown in FIG. 7A, there remain on the surface of the wafer W a relatively large number of areas not coated with the coating liquid.

In the event that the coating liquid was applied such that the dicing lines D and the coating liquid lines L crossed each other as shown in FIG. 7B, a though there exits areas not coated with the coating liquid, the number thereof was decreased.

Whether adjacent coating liquid lines L can properly be merged with each other or rot depends on coating conditions such as the width of the coating liquid, the composition of the coating liquid, and the dimensions (width, height, depth) of the dicing line and the patterns (ridge, groove). Thus, even when the direction of the dicing lines or patterns are parallel to the coating liquid lines L, there may be a situation in which the adjacent coating liquid lines L can properly be merged with each other. Accordingly, the coating liquid lines L should not necessarily be parallel to all the dicing lines and patterns. It is sufficient that a certain pattern (a pattern which may obstruct the merging of adjacent coating liquid lines L) of a plurality of patterns on the wafer W crosses the coating liquid lines L at a certain angle. Thus, it is possible that the above-described angle θ (see, FIG. 5) is 0 degree.

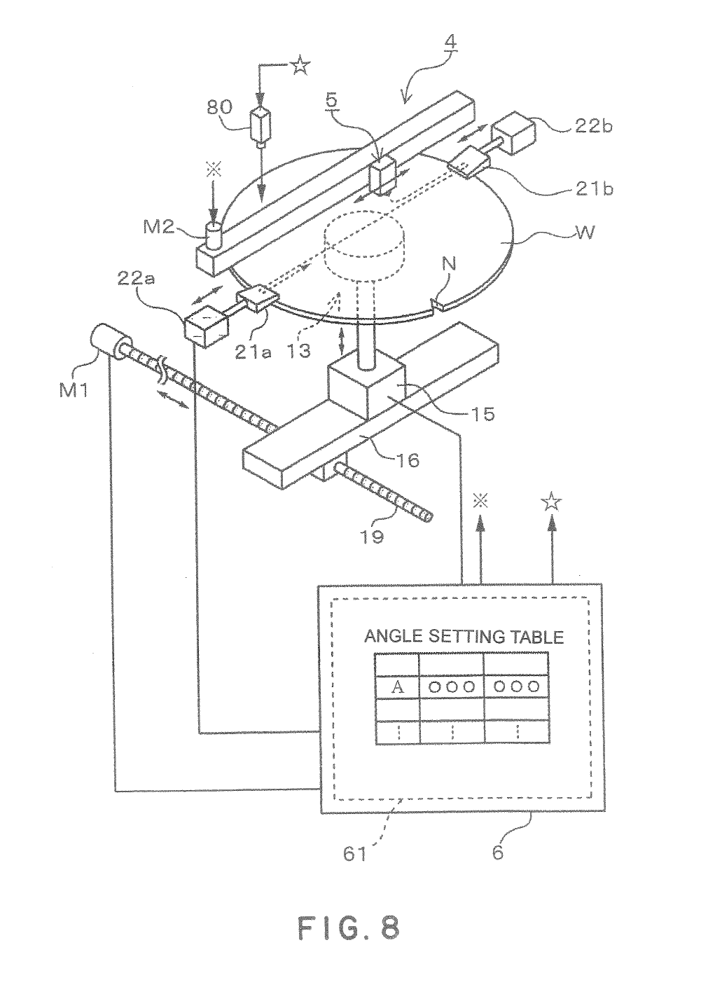

Another embodiment of the present invention will be described with reference to FIGS. 8 to 10. In the foregoing embodiment, the orientation of the wafer W is set by rotating the wafer W at a set angle defined by the recipe stored in the storing part 61. Meanwhile, in this embodiment, a CCD camera 80 as image-pickup means is disposed in the lower space 10a of a housing 10. The surface of the wafer W is imaged by the CCD camera 80 to read patterns such as wiring patterns on the wafer W, and the rotation angle of the wafer W is decided based on the result.

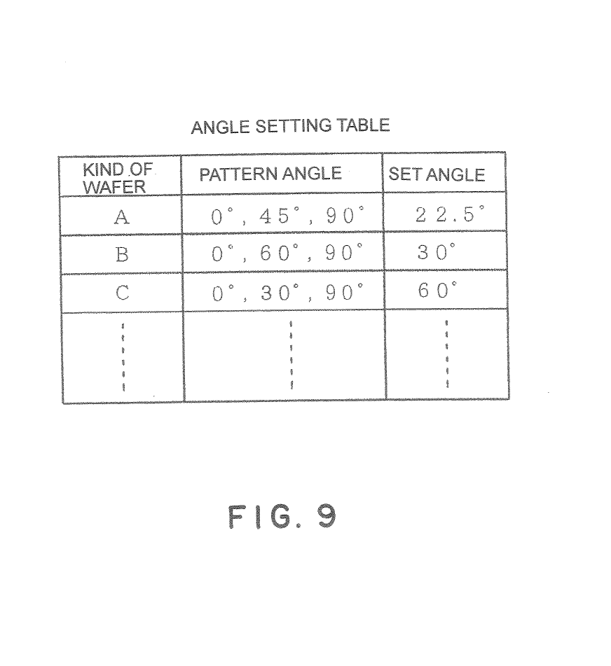

In detail, when the wafer W is transferred into the coating unit 1, the wafer W is moved to a position below the CCD camera 80 by operating the driving mechanism 18, and an area corresponding to one chip on the surface of the wafer W is imaged by the CCD camera 80. This imaging operation is carried out under conditions that a notch N is positioned on a front end or rear end of the wafer W. i.e., the angle θ shown in FIG. 5 is 0 degree. In this operation, instead of using the notch position detector 70, the notch N may be imaged by the CCD camera 80, and the angle θ of the wafer W is set to be 0 deg. based on the analysis of the obtained image. An angle setting table shown in FIG. 9 is stored in a storing part 61. The angle setting table records therein angles (pattern angles) of patterns of ridges or grooves in wiring patterns or the like, and associated angles (set angles) at which the wafer is rotated. The term “angle” herein means the above-stated angle θ shown in FIG. 5.

Angles of all the patterns on the wafer W are detected based on image data imaged by the CCD camera 80. With reference to the angle setting table, a set angle corresponding to a combination of the angles of the respective patterns is obtained. For example, when the angles of the respective patterns are 0°, 45°, and 90° the set angle of 22.5° corresponding to data of wafer-kind A is selected from the angle setting table shown in FIG. 9. Succeeding operations are carried out in the same manner as those previously described. In this embodiment, the storing part 61 and a program that reads out the set angle from the angle setting table and gives instructions to the driving base 15 correspond to the angle setting means.

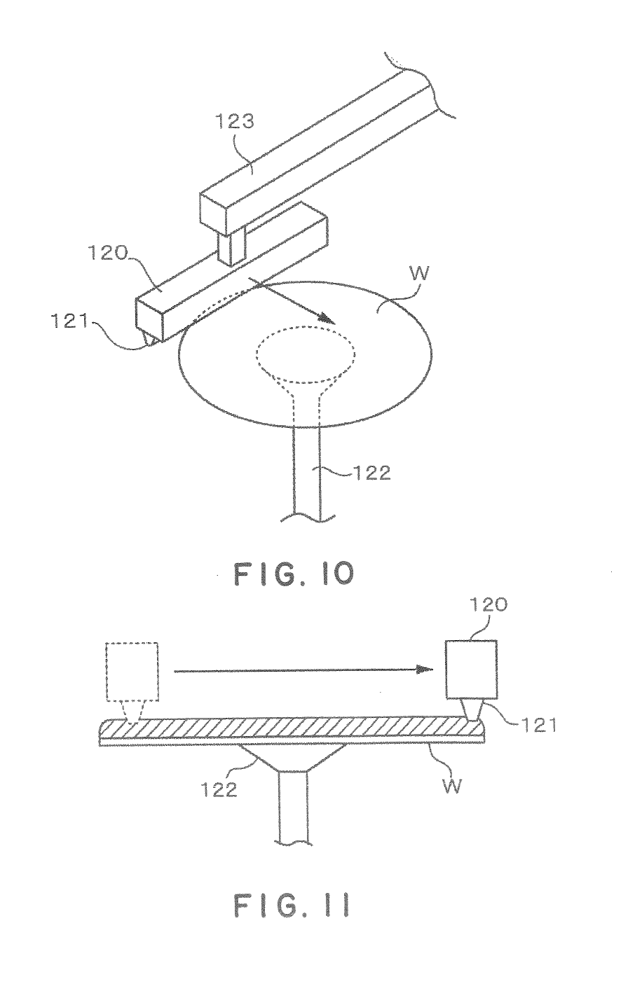

The apparatus and method according to the present invention is not limited to the use of a liquid coating nozzle with one dispense port forms a continuous, meandering coating liquid line; a liquid coating nozzle provided with a plurality of dispense ports arranged in a row (linearly) over the length corresponding to the width of the effective area of the substrate may be used for scanning application, as shown in FIGS. 10 to 12. The term “effective area” means an area of the substrate which is actually used as semiconductor integrated circuit elements, a liquid crystal panel and so on. The term “width of the effective area of the substrate” herein means, in a case that the substrate is a wafer W, a maximum value of the distance between two points at the intersections of a line passing through a center of the wafer W with the profile line (outer peripheral line) of the effective area. In order to obtain a uniform film thickness even in the outer peripheral portion of the effective area, it is preferable that the length of the area in which the dispense ports are arranged be set slightly larger than the width of the effective area.

In the embodiment shown in FIGS. 10 to 12, when a coating liquid is applied onto a surface of a wafer W held by the spin chuck 122 which is a substrate holding unit, the coating liquid is applied by moving a liquid coating nozzle 120 right above the effective area of the wafer W, with the coating liquid being dispensed from dispense ports 121 of the liquid coating nozzle 120, while the moving of the wafer W, which is performed in the previously-described embodiment, is not performed.

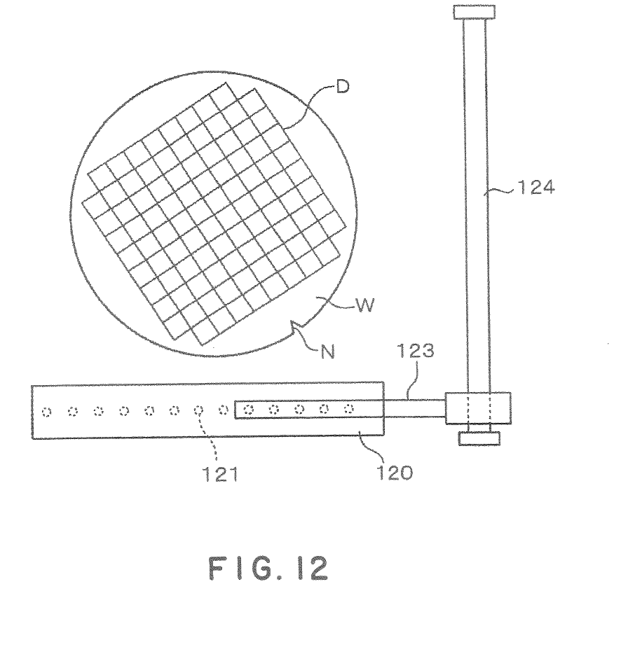

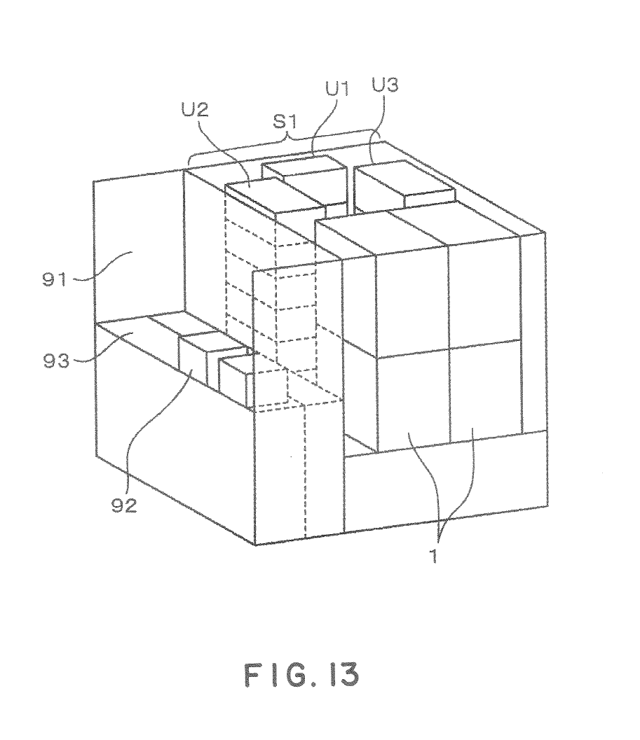

The liquid coating nozzle 120 has the plurality of dispense port 121 arranged in a row over the width of the effective area of the wafer W, i.e., a length corresponding to the diameter of the wafer W in this embodiment. As shown in FIGS. 11 and 12, the liquid coating nozzle 120 is supported by a nozzle supporting member 123 which is guided by a guide 124 to move in the longitudinal direction of the guide 124. In this state, the liquid coating nozzle 120 performs a translational movement from one end of the wafer W to the other end thereof so as to conduct scanning application of the coating liquid. In this manner, a plurality of linear coating liquid lines can be formed at once, so that the coating liquid is applied onto the whole area to be coated (effective area) of the wafer W to form a liquid film represented by the shaded portion shown in FIG. 11.

Also in the case of performing the application operation by means of such a liquid coating nozzle 120, as shown in FIG. 12, the coating liquid is applied by the liquid coating nozzle 120, with the wafer W being rotated by the spin chuck 122 at a predetermined angle in order that the dicing lines D and certain wiring patterns are not parallel to the scanning direction of the dispense ports 121, so that adjacent coating liquid lines are assuredly merged with each other without being obstructed by concavity and convexity, such as dicing lines D and the wiring patterns, formed on the surface of the wafer W. Thus, the area to be coated of the wafer W can entirely be coated with the coating liquid uniformly.

The liquid coating nozzle 120 is not limited to one having the plurality of dispense ports 120 linearly arranged over the length corresponding to the width of the effective area of the wafer W, i.e., the diameter of the wafer W. The liquid coating nozzle 120 may have the dispense ports 121 arranged over a length shorter than the width of the effective area of the wafer W, for example, a length corresponding the radius of the wafer W.

In the present invention, the coating liquid is not limited to the solution of the precursor of the insulation film but may be a resist liquid or the like. Further, not limited to the wafer W, the substrate may be a glass substrate for a liquid crystal display.

An example of a coating system incorporating the foregoing coating liquid forming apparatus is described with reference to FIGS. 13 and 14. The reference number 91 depicts a cassette station provided with: a cassette supporting table 93 that supports thereon a cassette 92 containing, e.g., 25 wafers W; and transfer means 94 that transfers the wafers W contained in the cassette 92 placed on the cassette supporting table 93. A processing section S1 surrounded by a housing 95 is connected on a back side of the transfer means 94. A main arm 96 as main conveying means is arranged at the center of the processing section S1. Around the main arm 96, there are arranged a plurality of unitized coating film forming apparatuses 1 (coating units) disposed on the right side when viewed from the cassette supporting table 93, a shelf unit U1 on the left side, a shelf unit U2 on the front side, and a shelf unit U3 on the back side. The respective shelf units U1 to U3 are formed by a heating unit, a cooling unit, and so on, which are laid in a stacking manner.

The unit shelves U1 to U3 are constituted by combining units for a pre-treatment and a post-treatment of the coating treatment carried out by the coating unit 1. The combination includes a vacuum drying unit for vacuum-drying a wafer on which a coating liquid has been applied by the coating unit 1, a heating unit for heating (baking) the wafer W, a cooling unit for cooling the wafer W, and so on. The unit shelf U3 includes a transfer unit provided with a table to be used for transferring the wafer. The main conveying means 96 is constituted to be capable of moving in a vertical direction and a forward-and-backward direction, and also rotating about a vertical axis. Thus, the wafer W can be transferred among the respective units, i.e., the coating unit 1 and the units in the unit shelves U1 to U3.

The flow of the wafer W in the coating system is as follows. First, the cassette 92 containing the wafers W is loaded into the coating system from outside, and placed on the cassette supporting table 93. The transfer means 94 takes out the wafer W from the cassette 92, and delivers the same to the main conveying means 96 through the transfer unit which is one of the units in the heating/cooling unit shelf U3. Then, the wafer W is subjected to a wafer-temperature stabilizing process in one of processing unit of the unit shelf U3, and then the coating liquid is applied onto the wafer W by the coating unit 1. Thereafter, the wafer W is vacuum-dried in the vacuum drying unit, heated in the heating unit, and cooled in the cooling unit to a predetermined temperature. Subsequently, the wafer W is returned into the cassette 92 placed on the cassette supporting table 93.

The orientation of the wafer W is changed in the coating unit 1 as described above, but is returned to the original orientation after completion of the coating process. That is, when the wafer W is conveyed by the main conveying means (main arm) 96, the notch N of the wafer W is always positioned on a front end or a rear end of the arm. Accordingly, change in the angle of the wafer in the coating unit 1 does not affect the process when the wafer W is subjected to a heating process or the like in other units.

1-18. (canceled)

19. A coating film forming method for forming a coating film on a surface of a substrate on which a plurality of patterns of grooves or ridges are formed, by dispensing a coating liquid from a liquid coating nozzle, said method comprising:
horizontally holding the substrate by a substrate holding member;
imaging a surface of the substrate;
determining directions of the plurality of patterns based on an imaging result, and orienting the substrate in an orientation, determined based on data structured so as to associate directions of plurality of patterns with orientations in each of which a substrate is to be oriented, so that each of the plurality of patterns on the substrate crosses a scanning direction of the liquid coating nozzle; and
linearly scanning the liquid coating nozzle relative to the substrate, while dispensing a coating liquid from the liquid coating nozzle.

20. The coating film forming method according to claim 19, further comprising arraying a plurality of linear coating liquid lines in a forward-and-backward direction, by repeating an operation in which the liquid coating nozzle is moved in a right-and-left direction to linearly apply the coating liquid on the surface of the substrate, and an operation in which the substrate holding member is moved relative to the liquid coating nozzle in the forward-and-backward direction at a preset pitch.

21. The coating film forming method according to claim 19, further comprising linearly scanning the liquid coating nozzle relative to the substrate, from one end of the substrate to the other end thereof, the liquid coating nozzle being provided with a plurality of linearly-arranged dispense ports for dispensing the coating liquid.

22. The coating film forming method according to claim 19, further comprising returning the substrate to an orientation in which the substrate was oriented when the substrate was delivered to the substrate holding member before starting of a coating process, prior to removing the substrate having been subjected to the coating process from the substrate holding member.

23. The coating film forming method according to claim 20, further comprising returning the substrate to an orientation in which the substrate was oriented when the substrate was delivered to the substrate holding member before starting of a coating process, prior to removing the substrate having been subjected to the coating process from the substrate holding member.

24. The coating film forming method according to claim 21, further comprising returning the substrate to an orientation in which the substrate was oriented when the substrate was delivered to the substrate holding member before starting of a coating process, prior to removing the substrate having been subjected to the coating process from the substrate holding member.

25. A coating film forming method for forming a coating film on a surface of a substrate on which a pattern of grooves or ridges are formed, by dispensing a coating liquid from a liquid coating nozzle, said method comprising:
horizontally holding the substrate by a substrate holding member;
retrieving, from data structured so as to associate kinds of substrates with orientations in each of which a substrate is to be oriented, an orientation in which the substrate to be coated is to be oriented, and orienting the substrate in the orientation so that the pattern on the substrate to be coated crosses a scanning direction of the liquid coating nozzle; and
linearly scanning the liquid coating nozzle relative to the substrate, while dispensing a coating liquid from the liquid coating nozzle.

26. The coating film forming method according to claim 25, further comprising arraying a plurality of linear coating liquid lines in a forward-and-backward direction, by repeating an operation in which the liquid coating nozzle is moved in a right-and-left direction to linearly apply the coating liquid on the surface of the substrate, and an operation in which the substrate holding member is moved relative to the liquid coating nozzle in the forward-and-backward direction at a preset pitch.

27. The coating film forming method according to claim 25, further comprising linearly scanning the liquid coating nozzle relative to the substrate, from one end of the substrate to the other end thereof, the liquid coating nozzle being provided with a plurality of linearly-arranged dispense ports for dispensing the coating liquid.

28. The coating film forming method according to claim 25, further comprising returning the substrate to an orientation in which the substrate was oriented when the substrate was delivered to the substrate holding member before starting of a coating process, prior to removing the substrate having been subjected to the coating process from the substrate holding member.

29. The coating film forming method according to claim 26, further comprising returning the substrate to an orientation in which the substrate was oriented when the substrate was delivered to the substrate holding member before starting of a coating process prior to removing the substrate having been subjected to the coating process from the substrate holding member.

30. The coating film forming method according to claim 27, further comprising returning the substrate to an orientation in which the substrate was oriented when the substrate was delivered to the substrate holding member before starting of a coating process, prior to removing the substrate having been subjected to the coating process from the substrate holding member.

31. A coating film forming apparatus for forming a coating film on a surface of a substrate on which a plurality of patterns of grooves or ridges are formed, said apparatus comprising:
a substrate holding member adapted to support a substrate horizontally,
a liquid coating nozzle opposed to the substrate held by the substrate holding member, the liquid coating nozzle being adapted to dispense a coating liquid to the substrate;
image-pickup means for imaging a surface of the substrate;
angle setting means including storage means for storing data structured so as to associate directions of plurality of patterns with orientations in each of which a substrate is to be oriented, the angle setting means being configured to determine directions of the plurality of patterns based on an imaging result obtained by the imaging means, and configured to orient the substrate to an orientation so that each of the plurality of patterns on the substrate crosses a scanning direction of the liquid coating nozzle; and
a driving mechanism adapted to cause the liquid coating nozzle to be moved relative to the substrate holding member such that the liquid coating nozzle linearly scans the substrate relatively.

32. The coating film forming apparatus according to claim 31, further comprising a first driving mechanism adapted to cause the substrate holding member to be moved in a forward-and-backward direction relative to the liquid coating nozzle, and a second driving mechanism adapted to move the liquid coating nozzle in a right-and-left direction, whereby a plurality of linear coating liquid lines are arrayed in the forward-and-backward direction to form a film of the coating liquid on the substrate, by repeating an operation in which, after the liquid coating nozzle is moved in the right-and-left direction while liquid coating nozzle dispenses the coating liquid, the substrate holding member is moved in a forward-and-backward direction relative to the liquid coating nozzle at a preset pitch.

33. The coating film forming apparatus according to claim 31, wherein:
the liquid coating nozzle is provided with a plurality of linearly-arranged dispense ports for dispensing the coating liquid; and
the driving mechanism is configured to cause the liquid coating nozzle to be moved relative to the substrate holding member so that the liquid coating nozzle to linearly scan the substrate relatively from one end of the substrate to the other end thereof.

34. The coating film forming apparatus according to claim 31, further comprising means for returning the substrate to an orientation in which the substrate was oriented when the substrate was delivered to the substrate holding member before starting of a coating process, prior to removing the substrate having been subjected to the coating process from the substrate holding member.

35. A coating film forming apparatus for forming a coating film on a surface of a substrate on which a pattern of grooves or ridges are formed, said apparatus comprising:
a substrate holding member adapted to support a substrate horizontally;
a liquid coating nozzle opposed to the substrate held by the substrate holding member, the liquid coating nozzle being adapted to dispense a coating liquid to the substrate;
angle setting means including storage means for storing data structured so as to associate kinds of substrates with orientations in each of which a substrate is to be oriented, the angle setting means being configured to retrieve an orientation in which the substrate to be coated is to be oriented, and configured to orient the substrate to the orientation so that each of the plurality of patterns on the substrate crosses a scanning direction of the liquid coating nozzle;
a driving mechanism adapted to cause the liquid coating nozzle to be moved relative to the substrate holding member such that the liquid coating nozzle linearly scans the substrate relatively.

36. The coating film forming apparatus according to claim 35, further comprising a first driving mechanism adapted to cause the substrate holding member to be moved in a forward-and-backward direction relative to the liquid coating nozzle, and a second driving mechanism adapted to move the liquid coating nozzle in a right-and-left direction, whereby a plurality of linear coating liquid lines are arrayed in the forward-and-backward direction to form a film of the coating liquid on the substrate, by repeating an operation in which, after the liquid coating nozzle is moved in the right-and-left direction while liquid coating nozzle dispenses the coating liquid, the substrate holding member is moved in a forward-and-backward direction relative to the liquid coating nozzle at a preset pitch.

37. The coating film forming apparatus according to claim 35, wherein:
the liquid coating nozzle is provided with a plurality of linearly-arranged dispense ports for dispensing the coating liquid; and
the driving mechanism is configured to cause the liquid coating nozzle to be moved relative to the substrate holding member so that the liquid coating nozzle to linearly scan the substrate relatively from one end of the substrate to the other end thereof.

38. The coating film forming apparatus according to claim 35, further comprising means for returning the substrate to an orientation in which the substrate was oriented when the substrate was delivered to the substrate holding member before starting of a coating process, prior to removing the substrate having been subjected to the coating process from the substrate holding member.
